(19) United States
(12) Patent Application Publication
(10) Pub. No.: US 2026/0293125 A1
(43) Pub. Date: Sep. 24, 2026

(54) SEMICONDUCTOR DEVICE

(71) Applicant: SAMSUNG ELECTRONICS CO., LTD., Suwon-si (KR)

(72) Inventor: Cheonbae KIM, Suwon-si (KR)

(73) Assignee: SAMSUNG ELECTRONICS CO., LTD., Suwon-si (KR)

(21) Appl. No.: 19/552,695

(22) Filed: Feb. 27, 2026

(30) Foreign Application Priority Data
Mar. 19, 2025 (KR) 10-2025-0035524

(51) Int. Cl. H10B 12/00

(52) U.S. Cl. CPC H10B 12/50; H10B 12/09

(57) ABSTRACT

There is provided a semiconductor device comprising a substrate comprising a cell array area and a peripheral circuit area, a cell capacitor disposed on the cell array area of the substrate and comprising a first lower electrode, a first capacitor dielectric layer, and a first upper electrode, and a decoupling capacitor disposed on the peripheral circuit area of the substrate and comprising a second lower electrode, a second capacitor dielectric layer, and a second upper electrode, wherein, from a plan view, an arrangement structure of the first lower electrode is different from an arrangement structure of the second lower electrode.

### CROSS-REFERENCE TO RELATED APPLICATION

This application is based on and claims priority under 35 U.S.C. §119 to Korean Patent Application No. 10-2025-0035524, filed on Mar. 19, 2025, in the Korean Intellectual Property Office, the disclosure of which is incorporated by reference herein in its entirety.

### BACKGROUND

The disclosure relates to a semiconductor device, and more particularly, to a semiconductor device comprising a capacitor.

As semiconductor devices become large-capacity and highly integrated, design rules are also continuously decreasing. This trend is also evident in a dynamic random array memory (DRAM) device, one of the memory semiconductor devices. For the DRAM device to operate, each cell requires a certain level of capacitance or higher. Transistors and cell capacitors may be included in a memory cell of the DRAM device, and decoupling capacitors may be included in a peripheral circuit of the DRAM device.

### SUMMARY

The disclosure provides a semiconductor device with improved integration of a decoupling capacitor.

According to an aspect of the disclosure, there is provided a semiconductor device comprising a substrate comprising a cell array area and a peripheral circuit area, a cell capacitor disposed on the cell array area of the substrate and comprising a first lower electrode, a first capacitor dielectric layer, and a first upper electrode, and a decoupling capacitor disposed on the peripheral circuit area of the substrate and comprising a second lower electrode, a second capacitor dielectric layer, and a second upper electrode, wherein, in a plan view, an arrangement structure of the first lower electrode is different from an arrangement structure of the second lower electrode.

According to another aspect of the disclosure, there is provided a semiconductor device comprising a substrate comprising a cell array area and a peripheral circuit area, a cell capacitor disposed on the cell array area of the substrate and comprising a plurality of first lower electrodes, a first capacitor dielectric layer, and a first upper electrode, and a decoupling capacitor disposed on the peripheral circuit area of the substrate, and comprising a plurality of second lower electrodes, a second capacitor dielectric layer, and a second upper electrode, wherein the plurality of first lower electrodes comprises a first arrangement structure in a first area, wherein the plurality of second lower electrodes comprises a second arrangement structure in a second area, and wherein a second density per unit area of the plurality of second lower electrodes in the second area is greater than a first density per unit area of the plurality of first lower electrodes in the first area.

According to another aspect of the disclosure, there is provided a semiconductor device comprising a substrate comprising a cell array area and a peripheral circuit area, a lower structure disposed on the substrate, a cell capacitor disposed on the cell array area of the substrate, the cell capacitor comprising, a plurality of first lower electrodes extending in a direction perpendicular to an upper surface of the substrate, a first capacitor dielectric layer covering the plurality of first lower electrodes, and a first upper electrode covering the plurality of first lower electrodes on the first capacitor dielectric layer, and a decoupling capacitor disposed on the peripheral circuit area of the substrate, the decoupling capacitor comprising, a plurality of second lower electrodes extending in the direction perpendicular to the upper surface of the substrate, a second capacitor dielectric layer covering the plurality of second lower electrodes, and a second upper electrode covering the plurality of second lower electrodes on the second capacitor dielectric layer, wherein the plurality of first lower electrodes are arranged at respective corners of a square, and the plurality of second lower electrodes are arranged at respective vertices of a regular hexagon and at a center of the regular hexagon.

According to another aspect of the disclosure, there is provided a method of manufacturing a semiconductor device, the method comprising preparing a substrate comprising a cell array area and a peripheral circuit area, and forming a lower structure on the substrate, forming a mold stack on the lower structure, forming a mask pattern on the mold stack, forming a first lower electrode hole penetrating the mold stack in the cell array area and a second lower electrode hole penetrating the mold stack in the peripheral circuit area, by using the mask pattern as an etching mask, and forming a first lower electrode and a second lower electrode by filling the first lower electrode hole and the second lower electrode hole with a conductive material, respectively, wherein, in a plan view, an arrangement structure of the first lower electrode is different from an arrangement structure of the second lower electrode.

In some embodiments, the semiconductor manufacturing method is provided, in which, in the forming of the first lower electrode hole, the first lower electrode hole is formed such that the first lower electrode hole is arranged at each vertex of a quadrangle, and in the forming of the second lower electrode hole, the second lower electrode hole is formed such that the second lower electrode hole is arranged at each vertex of a hexagon and at a center of the hexagon.

In some embodiments, the semiconductor manufacturing method is provided, in which, in the forming of the first lower electrode hole, the first lower electrode hole is formed such that the first lower electrode holes are spaced apart from each other by a first distance in a first horizontal direction and spaced apart from each other by a second distance in a second horizontal direction intersecting the first horizontal direction, and the first distance is equal to the second distance.

In some embodiments, the semiconductor manufacturing method is provided, in which, in the forming of the second lower electrode hole, the second lower electrode hole is formed such that the second lower electrode hole is spaced apart from each other by the first distance in a first horizontal direction and in a diagonal direction having a certain angle with the first horizontal direction.

In some embodiments, the semiconductor manufacturing method is provided, in which the forming of the first lower electrode hole and the forming of the second lower electrode hole each comprise single patterning, double patterning, quadruple patterning, or a combination thereof.

In some embodiments, the semiconductor manufacturing method is provided, in which the forming of the mask pattern comprises forming a first mask pattern on the mold stack in the cell array area, and forming a second mask pattern on the mold stack in the peripheral circuit area, and the first mask pattern comprises a plurality of first openings having a quadrangle arrangement structure, and the second mask pattern comprises a plurality of second openings having a honeycomb arrangement structure.

In some embodiments, the semiconductor manufacturing method is provided, in which the forming of the first mask pattern and the forming of the second mask pattern are performed simultaneously.

In some embodiments, the semiconductor manufacturing method is provided, in which, in the forming of the first lower electrode and the second lower electrode, the first lower electrode and the second lower electrode are formed such that a diameter of the first lower electrode is less than a diameter of the second lower electrode.

In some embodiments, the semiconductor manufacturing method comprises forming of a plurality of first lower electrodes and a plurality of second lower electrodes, wherein a first density per unit area of the plurality of first lower electrodes is less than a second density per unit area of the plurality of second lower electrodes.

In some embodiments, the semiconductor manufacturing method further comprises forming a first capacitor dielectric layer covering the first lower electrode and a second capacitor dielectric layer covering the second lower electrode, and forming a first upper electrode covering the first capacitor dielectric layer and a second upper electrode covering the second capacitor dielectric layer.

### BRIEF DESCRIPTION OF DRAWINGS

Embodiments will be more clearly understood from the following detailed description taken in conjunction with the accompanying drawings in which:

FIG. 1 is a layout diagram illustrating a semiconductor device according to embodiments;

FIG. 2A is a plan view schematically illustrating an area A of FIG. 1;

FIG. 2B is a plan view schematically illustrating an area B of FIG. 1;

FIG. 3A is a cross-sectional view taken along a line A1-A1' of FIG. 2A;

FIG. 3B is a cross-sectional view taken along a line B1-B1' of FIG. 2B; and

FIGS. 4A and 4B to 9A and 9B are cross-sectional views illustrating a method of manufacturing a semiconductor device, according to embodiments, wherein FIGS. 4A, 6A, 7A, 8A, and 9A, are cross-sectional views taken along a line A1-A1' of FIG. 2A, FIGS. 4B, 6B, 7B, 8B, and 9B, are cross-sectional views taken along a line B1-B1' of FIG. 2B, and FIGS. 5A and 5B are plan views corresponding to areas A and B of FIG. 1, respectively.

### DETAILED DESCRIPTION

Hereinafter, embodiments are described in detail with reference to the attached drawings.

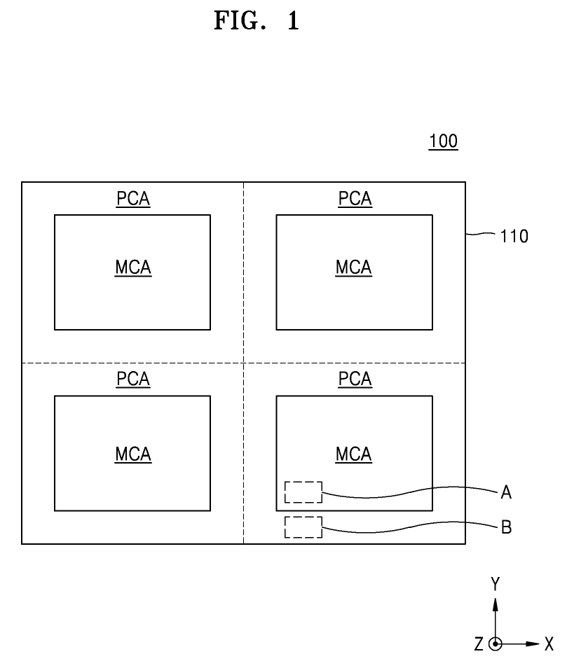

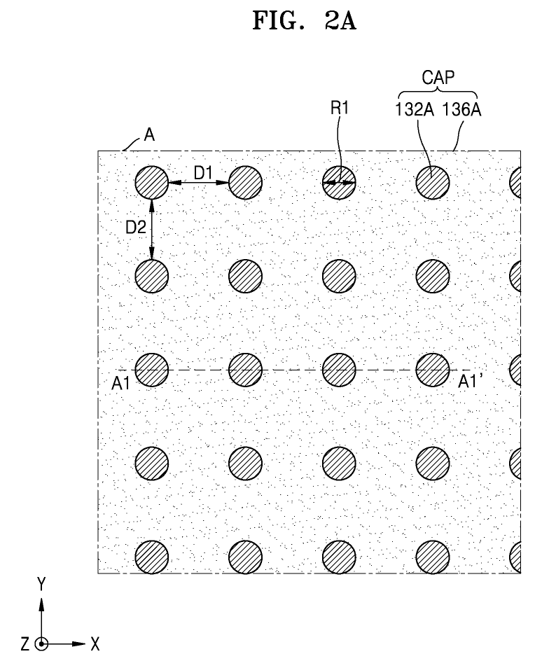

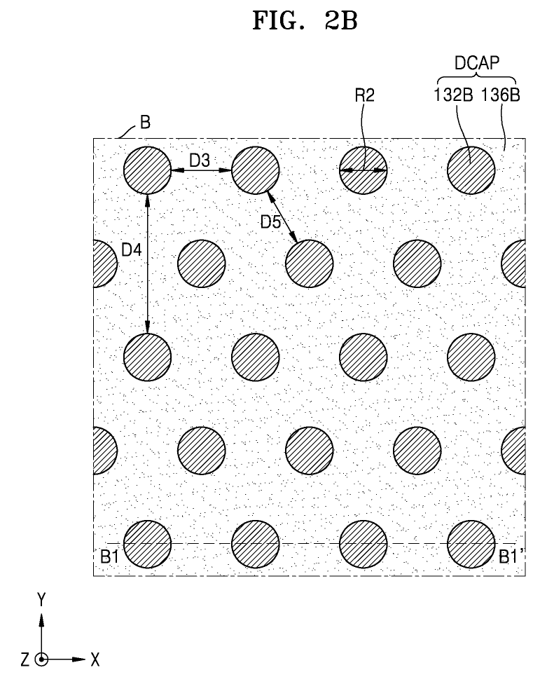

FIG. 1 is a layout diagram illustrating a semiconductor device 100 according to embodiments. FIG. 2A is a plan view schematically illustrating an area A of FIG. 1. FIG. 2B is a plan view schematically illustrating an area B of FIG. 1.

Referring to FIG. 1, the semiconductor device 100 may include a substrate 110 comprising a cell array area MCA and a peripheral circuit area PCA. The cell array area MCA may be a memory cell area of a random array memory (DRAM) device, and the peripheral circuit area PCA may be a core area or a peripheral circuit area of the DRAM device. For example, the cell array area MCA may include a cell transistor and a cell capacitor CAP (see FIG. 2A) connected thereto, and the peripheral circuit area PCA may include peripheral circuit transistors for transmitting signals and/or power to cell transistors included in the cell array area MCA. In embodiments, the peripheral circuit transistors may form various circuits such as command decoders, control logic, address buffers, row decoders, column decoders, sense amplifiers, and data input/output circuits. In addition, the peripheral circuit area PCA may include a decoupling capacitor area comprising a decoupling capacitor DCAP.

Referring to FIGS. 2A and 2B, the cell array area MCA may include a first area A comprising a plurality of cell capacitors CAP. The peripheral circuit area PCA may include a second area B comprising a plurality of decoupling capacitors DCAP. In this case, the second area B may mean the decoupling capacitor area.

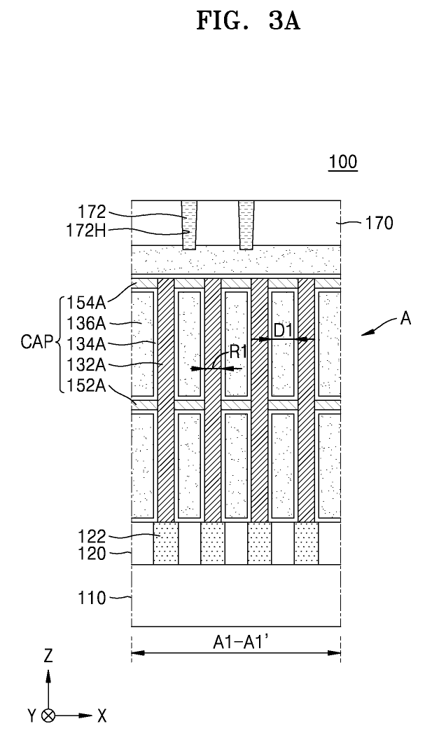

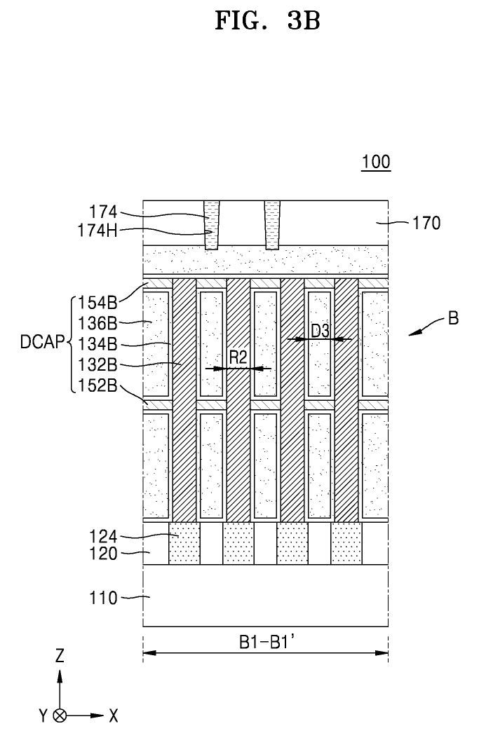

The plurality of cell capacitors CAP may include a plurality of first lower electrodes 132A and a first upper electrode 136A. The plurality of first lower electrodes 132A may be arranged to be spaced apart from each other in a first horizontal direction X and a second horizontal direction Y. The first upper electrode 136A may be arranged to cover the plurality of first lower electrodes 132A. A first capacitor dielectric layer 134A (see FIG. 3A) may be placed between the first lower electrode 132A and the first upper electrode 136A, but for convenience, an illustration of the first capacitor dielectric layer 134A may be omitted in FIG. 2A.

The plurality of decoupling capacitors DCAP may include a plurality of second lower electrodes 132B and a second upper electrode 136B. The plurality of second lower electrodes 132B may be arranged to be spaced apart from each other in the first horizontal direction X and the second horizontal direction Y. The second upper electrode 136B may be arranged to cover the plurality of second lower electrodes 132B. A second capacitor dielectric layer 134B (see FIG. 3B) may be placed between the second lower electrode 132B and the second upper electrode 136B, but for convenience, an illustration of the second capacitor dielectric layer 134B may be omitted in FIG. 2B.

In a plan view, an arrangement structure of the plurality of first lower electrodes 132A arranged in the first area A may be different from an arrangement structure of the plurality of second lower electrodes 132B arranged in the second area B. The plurality of first lower electrodes 132A may have a quadrangle arrangement structure, and the plurality of second lower electrodes 132B may have a polygonal arrangement structure rather than the quadrangle arrangement structure. For example, the plurality of second lower electrodes 132B may have a hexagonal arrangement structure.

In embodiments, the plurality of first lower electrodes 132A may be arranged to be spaced apart from each other by a first distance D1 in the first horizontal direction X and to be spaced apart from each other by a second distance D2 in the second horizontal direction Y. The plurality of first lower electrodes 132A may be arranged at respective corners of the quadrangle. In some embodiments, the plurality of first lower electrodes 132A may be placed at respective corners of a square. For example, the plurality of first lower electrodes 132A may be arranged such that the first distance D1 is equal to the second distance D2. In another embodiment, the plurality of first lower electrodes 132A may be arranged at respective corners of the rectangle. For example, the plurality of first lower electrodes 132A may be arranged such that the first distance D1 is different from the second distance D2.

In embodiments, the plurality of second lower electrodes 132B may be arranged to be spaced apart from each other by a third distance D3 in the first horizontal direction X and to be spaced apart from each other by a fourth distance D4 in the second horizontal direction Y. In this case, the third distance D3 may be equal to the first distance D1, and the fourth distance D4 may be greater than the first distance D1.

The plurality of second lower electrodes 132B may be arranged at respective corners of a hexagon and at a center of the hexagon. Six neighboring second lower electrodes 132B may be arranged around one second lower electrode 132B. In some embodiments, the plurality of second lower electrodes 132B may be arranged at respective corners of a regular hexagon and at a center of the regular hexagon. For example, the plurality of second lower electrodes 132B may be arranged in a honeycomb structure.

In embodiments, to form the honeycomb structure, the plurality of second lower electrodes 132B may be arranged such that a ratio of a pitch of the second lower electrodes 132B in the first horizontal direction X and a pitch of the second lower electrodes 132B in the second horizontal direction Y is 1:1.73. In addition, the plurality of second lower electrodes 132B are arranged to have a fifth distance D5 in a diagonal direction, and the fifth distance D5 may be equal to the first distance D1. In this case, the diagonal direction may mean a direction having an angle of 60 degrees or 120 degrees with the first horizontal direction X.

A diameter R1 of the first lower electrode 132A may be less than a diameter R2 of the second lower electrode 132B. An area occupied by the plurality of first lower electrodes 132A per unit area in the first area A may be less than an area occupied by the plurality of second lower electrodes 132B per unit area in the second area B. That is, a first density per unit area of the plurality of first lower electrodes 132A in the first area A may be less than a second density per unit area of the plurality of second lower electrodes 132B in the second area B. Because the diameter R1 of the first lower electrode 132A is different from the diameter R2 of the second lower electrode 132B and the first distance D1 is equal to the third distance D3, a pitch of the first lower electrodes 132A in the first horizontal direction X may be different from a pitch of the second lower electrodes 132B in the first horizontal direction X. For example, the pitch of the second lower electrodes 132B (e.g., 2R2+D3) may be greater than the pitch of the first lower electrodes 132A (e.g., 2R1+D1). Here, the pitch may mean a distance between centers of adjacent lower electrodes.

In the semiconductor device 100 of the disclosure, an arrangement structure of the plurality of cell capacitors CAP arranged in the cell array area MCA may be different from an arrangement structure of the plurality of decoupling capacitors DCAP arranged in the peripheral circuit area PCA. In detail, an arrangement structure of the first lower electrode 132A of the cell capacitor CAP may be different from an arrangement structure of the second lower electrode 132B of the decoupling capacitor DCAP. Unlike the plurality of first lower electrodes 132A arranged in a quadrangle shape, by arranging the plurality of second lower electrodes 132B in the honeycomb structure, a density of the plurality of second lower electrodes 132B per unit area in the decoupling capacitor area (e.g., the second area B) may increase. As a density of the plurality of second lower electrodes 132B per unit area increases, capacitance of the decoupling capacitor DCAP may be reduced, thereby improving electrical performance of the semiconductor device 100.

In addition, by arranging the plurality of cell capacitors CAP arranged in the cell array area MCA differently from the plurality of decoupling capacitors DCAP arranged in the peripheral circuit area PCA, degree of design freedom in the manufacturing process of the semiconductor device 100 may be increased.

FIG. 3A is a cross-sectional view taken along a line A1-A1' of FIG. 2A.

FIG. 3B is a cross-sectional view taken along a line B1-B1' of FIG. 2B.

Referring to FIGS. 3A and 3B, a lower structure 120 may be disposed on the substrate 110. A plurality of first conductive patterns 122 penetrating the lower structure 120 may be arranged on the cell array area MCA of the substrate 110, and a plurality of second conductive patterns 124 penetrating the lower structure 120 may be arranged on the peripheral circuit area PCA of the substrate 110.

In embodiments, the lower structure 120 may include an insulating film comprising a silicon oxide film, a silicon nitride film, or a combination thereof. In some other embodiments, the lower structure 120 may include various conductive areas, such as a wiring layer, a contact plug, a transistor, and the like, and an insulating film that insulates them from each other.

In embodiments, the plurality of first conductive patterns 122 and the plurality of second conductive patterns 124 may include polysilicon, metal, conductive metal nitride, metal silicide, or a combination thereof.

The cell capacitor CAP may be disposed on the substrate 110 in the first area A. The cell capacitor CAP may include the plurality of first lower electrodes 132A, the first capacitor dielectric layer 134A, the first upper electrode 136A, a first lower supporter pattern 152A, and a first upper supporter pattern 154A.

In embodiments, the plurality of first lower electrodes 132A may each extend in a vertical direction Z on the plurality of first conductive patterns 122. Each of the plurality of first lower electrodes 132A may have a pillar shape that extends in the vertical direction (Z direction) from an upper surface of the first conductive pattern 122 away from the substrate 110. Although an example where each of the plurality of first lower electrodes 132A has the pillar shape has been described, technical aspects of the disclosure are not limited thereto. For example, each of the plurality of first lower electrodes 132A may have a cross-sectional structure of a cup shape or a cylinder shape with a closed bottom.

The first lower supporter pattern 152A may be disposed on a first portion of a sidewall of the plurality of first lower electrodes 132A, and the first upper supporter pattern 154A may be arranged on a second portion of the sidewall of the plurality of first lower electrodes 132A. The first lower supporter pattern 152A may be a flat layer extending in the first horizontal direction X and/or the second horizontal direction Y, and the first upper supporter pattern 154A may be a flat layer extending in the first horizontal direction X and/or the second horizontal direction Y at a higher vertical level than the first lower supporter pattern 152A. The plurality of first lower electrodes 132A may pass through the first lower supporter pattern 152A and the first upper supporter pattern 154A to extend in the vertical direction Z.

In embodiments, an upper surface of the first lower electrode 132A may be arranged on the same plane as an upper surface of the first upper supporter pattern 154A, but technical aspects of the disclosure are not limited thereto.

The first lower supporter pattern 152A may be arranged to be spaced apart from the first upper supporter pattern 154A on the sidewall of the first lower electrode 132A. In another embodiment, an additional cell supporter pattern may be further arranged at a different vertical level from the first lower supporter pattern 152A and the first upper supporter pattern 154A, for example, between the first lower supporter pattern 152A and the first upper supporter pattern 154A.

In embodiments, the first capacitor dielectric layer 134A may be conformally arranged on the sidewall of the first lower electrode 132A and may extend onto top and bottom surfaces of the first lower supporter pattern 152A and onto top and bottom surfaces of the first upper supporter pattern 154A.

The first upper electrode 136A may be disposed on the first capacitor dielectric layer 134A and may be disposed to cover the plurality of first lower electrodes 132A, the first lower supporter pattern 152A, and the first upper supporter pattern 154A.

The decoupling capacitor DCAP may be disposed on the substrate 110 in the second area B. The decoupling capacitor DCAP may comprise the plurality of second lower electrodes 132B, the second capacitor dielectric layer 134B, the second upper electrode 136B, a second lower supporter pattern 152B, and a second upper supporter pattern 154B.

In embodiments, the plurality of second lower electrodes 132B may each extend in the vertical direction Z on the plurality of second conductive patterns 124. Each of the second lower electrodes 132B may have a pillar shape that extends in a vertical direction (Z direction) away from the substrate 110 from an upper surface of the second conductive pattern 124. Although the case in which each of the plurality of second lower electrodes 132B has the pillar shape has been described as an example, technical aspects of the disclosure are not limited thereto. For example, each of the second lower electrodes 132B may have the cross-sectional structure of the cup shape or the cylinder shape with the closed bottom.

The second lower supporter pattern 152B may be arranged on a first portion of a sidewall of the plurality of second lower electrodes 132B, and the first upper supporter pattern 154A may be disposed on a second portion of the sidewall of the plurality of second lower electrodes 132B. The second lower supporter pattern 152B may be the flat layer extending in the first horizontal direction X and/or the second horizontal direction Y, and the second upper supporter pattern 154B may be the flat layer extending in the first horizontal direction X and/or the second horizontal direction Y at a higher vertical level than the second lower supporter pattern 152B. The plurality of second lower electrodes 132B may pass through the second lower supporter pattern 152B and the second upper supporter pattern 154B to extend in the vertical direction Z.

In embodiments, an upper surface of the second lower electrode 132B may be arranged on the same plane as an upper surface of the second upper supporter pattern 154B, but technical aspects of the disclosure are not limited thereto.

The second lower supporter pattern 152B may be arranged spaced apart from the second upper supporter pattern 154B on the sidewall of the second lower electrode 132B. In another embodiment, an additional cell supporter pattern may be further arranged at a different vertical level from the second lower supporter pattern 152B and the second upper supporter pattern 154B, for example, between the second lower supporter pattern 152B and the second upper supporter pattern 154B.

In embodiments, the second capacitor dielectric layer 134B may be conformally arranged on the sidewall of the second lower electrode 132B and may extend onto top and bottom surfaces of the second lower supporter pattern 152B and onto top and bottom surfaces of the second upper supporter pattern 154B.

The second upper electrode 136B may be disposed on the second capacitor dielectric layer 134B and may be disposed to cover the plurality of second lower electrodes 132B, the second lower supporter pattern 152B, and the second upper supporter pattern 154B.

In embodiments, each of the plurality of first lower electrodes 132A and the plurality of second lower electrodes 132B may comprise Ti, TiN, Ta, TaN, W, WN, TiSiN, WSiN, or a combination thereof.

In embodiments, the first lower supporter pattern 152A, the first upper supporter pattern 154A, the second lower supporter pattern 152B, and the second upper supporter pattern 154B may each comprise silicon nitride, silicon carbon nitride, silicon boron nitride, or a combination thereof. In embodiments, the first upper supporter pattern 154A may comprise the same material as the first lower supporter pattern 152A or may comprise a different material than the first lower supporter pattern 152A. The second upper supporter pattern 154B may comprise the same material as the second lower supporter pattern 152B or may comprise a different material than the second lower supporter pattern 152B.

In embodiments, the first capacitor dielectric layer 134A and the second capacitor dielectric layer 134B may each comprise a high-k dielectric layer. The high-k dielectric layer may refer to a dielectric layer having a higher dielectric constant than a silicon oxide layer. For example, the first capacitor dielectric layer 134A may comprise a metal oxide comprising at least one metal selected from hafnium (Hf), zirconium (Zr), aluminum (Al), niobium (Nb), cerium (Ce), lanthanum (La), tantalum (Ta), and titanium (Ti).

In embodiments, the first capacitor dielectric layer 134A and the second capacitor dielectric layer 134B may each comprise a ferroelectric material layer, an antiferroelectric material layer, a paraelectric material layer, or a combination thereof. In some embodiments, the first capacitor dielectric layer 134A and the second capacitor dielectric layer 134B may each have a stacked structure of a first dielectric layer composed of a ferroelectric material layer and a second dielectric layer composed of an antiferroelectric material layer. In some embodiments, the first capacitor dielectric layer 134A and the second capacitor dielectric layer 134B may each have a stacked structure of the first dielectric layer composed of the ferroelectric material layer and a second dielectric layer composed of a paraelectric material layer.

In embodiments, the first upper electrode 136A and the second upper electrode 136B may comprise Ti, TiN, Ta, TaN, W, WN, TiSiN, WSiN, Si, SiGe, or a combination thereof.

In embodiments, an upper insulating layer 170 may be disposed on upper surfaces of the cell capacitor CAP and the decoupling capacitor DCAP. In the first area A, a first upper contact 172 may be placed within a first contact hole 172H penetrating the upper insulating layer 170. The first upper contact 172 may be disposed on an upper surface of the first upper electrode 136A and electrically connected to the first upper electrode 136A. In the second area B, a second upper contact 174 may be placed within a second contact hole 174H penetrating the upper insulating layer 170. The second upper contact 174 may be disposed on an upper surface of the second upper electrode 136B and electrically connected to the second upper electrode 136B.

In the plan view, the arrangement structure of the plurality of first lower electrodes 132A arranged in the first area A may be different from the arrangement structure of the plurality of second lower electrodes 132B arranged in the second area B. The plurality of first lower electrodes 132A may have a square arrangement structure, and the plurality of second lower electrodes 132B may have the hexagonal arrangement structure.

In embodiments, the plurality of first lower electrodes 132A may be arranged to be spaced apart from each other by the first distance D1 in the first horizontal direction X, and the plurality of second lower electrodes 132B may be arranged to be spaced apart from each other by the third distance D3 in the first horizontal direction X. In this case, the third distance D3 may be equal to the first distance D1.

In embodiments, the diameter R1 of the first lower electrode 132A may be less than the diameter R2 of the second lower electrode 132B. The area occupied by the plurality of first lower electrodes 132A per unit area in the first area A may be less than the area occupied by the plurality of second lower electrodes 132B per unit area in the second area B. That is, the first density per unit area of the plurality of first lower electrodes 132A in the first area A may be less than the second density per unit area of the plurality of second lower electrodes 132B in the second area B.

The first lower supporter pattern 152A and the first upper supporter pattern 154A may be between adjacent first lower electrodes 132A in the first horizontal direction X. In addition, the second lower supporter pattern 152B and the second upper supporter pattern 154B may be between adjacent second lower electrodes 132B in the first horizontal direction X. In the semiconductor device 100 of the disclosure, the area occupied by the second lower electrode 132B per unit area may be greater than the area occupied by the first lower electrode 132A per unit area, or the second density per unit area of the plurality of second lower electrodes 132B may be greater than the first density per unit area of the plurality of first lower electrodes 132A. Accordingly, an area occupied by the first lower supporter pattern 152A per unit area may be greater than an area occupied by the second lower supporter pattern 152B per unit area, or a density per unit area of the first lower supporter pattern 152A may be greater than a density per unit area of the second lower supporter pattern 152B. In addition, an area occupied by the first upper supporter pattern 154A per unit area may be larger than the area occupied by the second upper supporter pattern 154B per unit area, or a density per unit area of the first upper supporter pattern 154A may be greater than a density per unit area of the second upper supporter pattern 154B. In embodiments, in the plan view, an arrangement of the first lower supporter pattern 152A may be different from an arrangement of the second lower supporter pattern 152B. In addition, in the plan view, an arrangement of the first upper supporter pattern 154A may be different from an arrangement of the second upper supporter pattern 154B.

In the semiconductor device 100 of the disclosure, the arrangement structure of the plurality of cell capacitors CAP arranged in the cell array area MCA may be different from the arrangement structure of the plurality of decoupling capacitors DCAP arranged in the peripheral circuit area PCA. In detail, the arrangement structure of the first lower electrode 132A of the cell capacitor CAP may be different from the arrangement structure of the second lower electrode 132B of the decoupling capacitor DCAP. Unlike the plurality of first lower electrodes 132A arranged in the quadrangle shape, by arranging the plurality of second lower electrodes 132B in the honeycomb structure, the second density per unit area of the plurality of second lower electrodes 132B in the decoupling capacitor area (e.g., the second area B) may increase. As the second density per unit area of the plurality of second lower electrodes 132B increases, the capacitance of the decoupling capacitor DCAP may be reduced, thereby improving electrical performance of the semiconductor device 100.

In addition, by arranging the plurality of cell capacitors CAP arranged in the cell array area MCA differently from the plurality of decoupling capacitors DCAP arranged in the peripheral circuit area PCA, the degree of design freedom in the manufacturing process of the semiconductor device 100 may be increased.

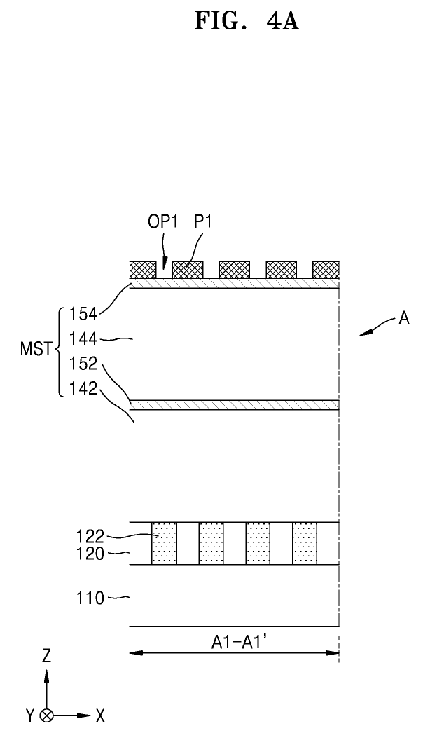

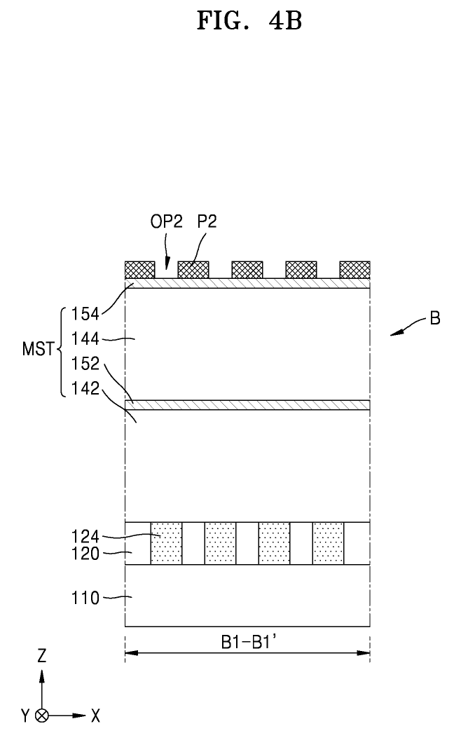

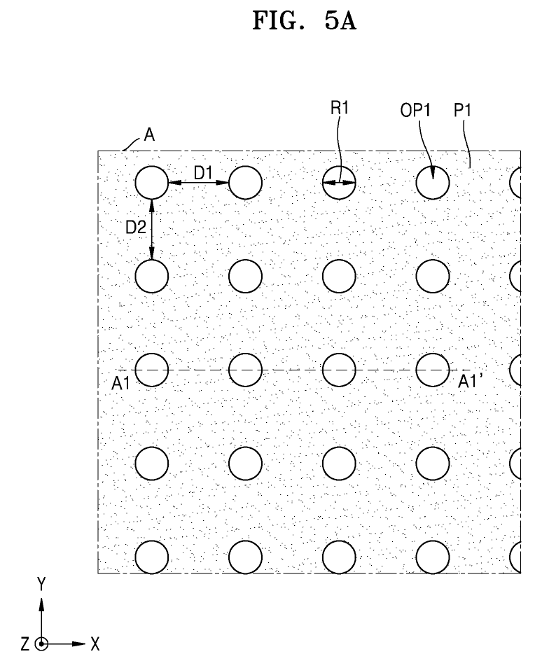

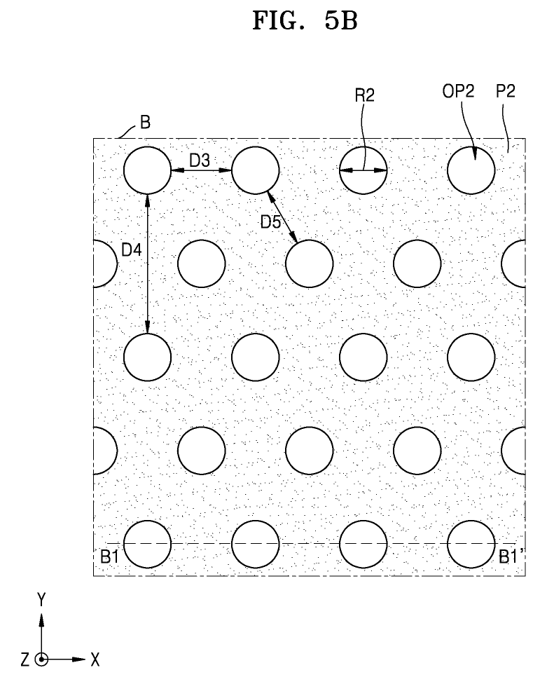

FIGS. 4A and 4B to 9A and 9B are cross-sectional views illustrating a method of manufacturing a semiconductor device, according to embodiments, wherein FIGS. 4A, 6A, 7A, 8A, and 9A are cross-sectional views taken along a line A1-A1’ of FIG. 2A, FIGS. 4B, 6B, 7B, 8B, and 9B are cross-sectional views taken along a line B1-B1’ of FIG. 2B, and FIGS. 5A and 5B are plan views corresponding to areas A and B of FIG. 1, respectively.

Referring to FIGS. 4A and 4B, the lower structure 120, the first conductive pattern 122, and the second conductive pattern 124 may be formed on the substrate 110 in the first area A and the second area B.

A mold stack MST may be formed by sequentially forming a first mold insulating layer 142, a first supporter layer 152, a second mold insulating layer 144, and a second supporter layer 154 on the lower structure 120. In this case, the mold stack MST may be arranged to cover the entire cell array area MCA and peripheral circuit area PCA.

In embodiments, the first mold insulating layer 142 and the second mold insulating layer 144 may comprise silicon oxide. In embodiments, the first supporter layer 152 and the second supporter layer 154 may comprise silicon nitride, silicon carbon nitride, silicon boron nitride, or a combination thereof.

In embodiments, the first supporter layer 152 may be formed using a material having an etching selectivity with respect to the first mold insulating layer 142, and the second supporter layer 154 may be formed using the material having an etching selectivity with respect to the second mold insulating layer 144.

Afterwards, a mask pattern may be formed on the mold stack MST. In detail, a first mask pattern P1 may be formed on the mold stack MST in the first area A, and a second mask pattern P2 may be formed on the mold stack MST in the second area B. In this case, the first mask pattern P1 may comprise a plurality of first openings OP1, and the second mask pattern P2 may comprise a plurality of second openings OP2.

Referring to FIGS. 5A and 5B, an arrangement structure of the plurality of first openings OP1 formed in the first mask pattern P1 and an arrangement structure of the plurality of second openings OP2 formed in the second mask pattern P2 may be substantially the same as the arrangement structure of the plurality of first lower electrodes 132A and the arrangement structure of the plurality of second lower electrodes 132B described above, respectively.

In the plan view, the arrangement structure of the plurality of first openings OP1 arranged in the first area A may be different from the arrangement structure of the plurality of second openings OP2 arranged in the second area B. The plurality of first openings OP1 may have the quadrangle arrangement structure, and the plurality of second openings OP2 may have the polygonal arrangement structure other than the quadrangle arrangement structure. For example, the plurality of second openings OP2 may have the hexagonal arrangement structure.

In embodiments, the plurality of first openings OP1 may be arranged to be spaced apart from each other by the first distance D1 in the first horizontal direction X and to be spaced apart from each other by the second distance D2 in the second horizontal direction Y. The plurality of first openings OP1 may be arranged at respective corners of the quadrangle. In some embodiments, the plurality of first openings OP1 may be arranged at respective corners of the square. For example, the plurality of first openings OP1 may be arranged so that the first distance D1 and the second distance D2 are equal to each other. In another embodiment, the plurality of first openings OP1 may be arranged at respective corners of the rectangle. For example, the plurality of first openings OP1 may be arranged so that the first distance D1 and the second distance D2 are different from each other.

In embodiments, the plurality of second openings OP2 may be arranged to be spaced apart from each other by the third distance D3 in the first horizontal direction X and to be spaced apart from each other by the fourth distance D4 in the second horizontal direction Y. In this case, the third distance D3 may be equal to the first distance D1, and the fourth distance D4 may be greater than the first distance D1.

The plurality of second openings OP2 may be arranged at respective corners of the hexagon and at the center of the hexagon. Six neighboring second openings OP2 may be arranged around one second opening OP2. In some embodiments, the plurality of second openings OP2 may be arranged at respective vertices of the regular hexagon and at the center of the regular hexagon. For example, the plurality of second openings OP2 may be arranged in the honeycomb structure.

In embodiments, to form the honeycomb structure, the plurality of second openings OP2 may be arranged such that the ratio of the pitch of the second lower electrodes 132B in the first horizontal direction X and the pitch of the second lower electrodes 132B in the second horizontal direction Y is 1:1.73. In addition, the plurality of second openings OP2 are arranged to have the fifth distance D5 in the diagonal direction, and the fifth distance D5 may be equal to the first distance D1. In this case, the diagonal direction may mean a direction having an angle of 60 degrees or 120 degrees with the first horizontal direction X.

A diameter R1 of the first opening OP1 may be less than a diameter R2 of the second opening OP2. An area occupied by the plurality of first openings OP1 per unit area in the first area A may be less than an area occupied by the plurality of second openings OP2 per unit area in the second area B, or a density per unit area of the plurality of first openings OP1 in the first area A may be less than a density per unit area of the plurality of second openings OP2 in the second area B.

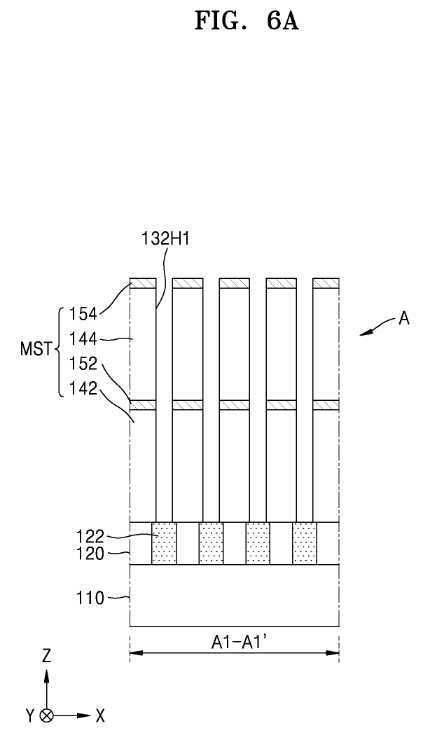

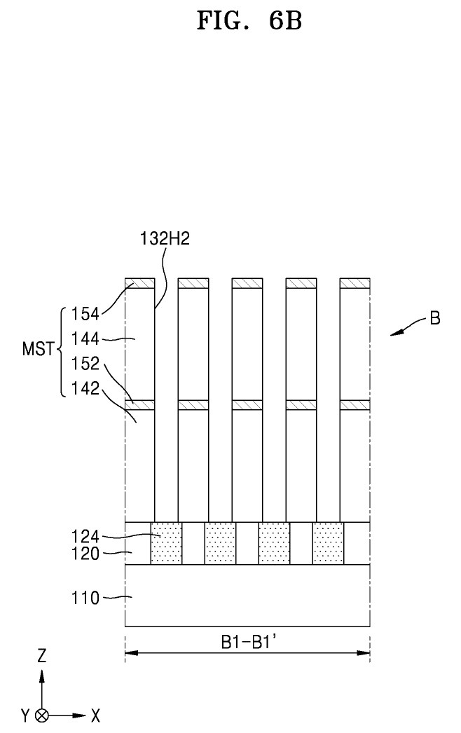

Referring to FIGS. 6A and 6B, in the first area A, a first lower electrode hole 132H1 may be formed by removing a portion of the mold stack MST by using the first mask pattern P1 as an etching mask in the first area A. In addition, in the second area B, a second lower electrode hole 132H2 may be formed by removing the portion of the mold stack MST by using the second mask pattern P2. In this case, a diameter of the first lower electrode hole 132H1 may correspond to a diameter of the first opening OP1 (see FIG. 5A), and a diameter of the second lower electrode hole 132H2 may correspond to the diameter of the second opening OP2 (see FIG. 5B). That is, the diameter of the first lower electrode hole 132H1 may be less than the diameter of the second lower electrode hole 132H2.

In embodiments, a process of forming the first lower electrode hole 132H1 may be performed at the same stage as a process of forming the second lower electrode hole 132H2. In other embodiments, the first lower electrode hole 132H1 may be formed first and then the second lower electrode hole 132H2 may be formed. In other embodiments, the second lower electrode hole 132H2 may be formed first and then the first lower electrode hole 132H1 may be formed.

In embodiments, the first lower electrode hole 132H1 may extend in the vertical direction Z so that the upper surface of the first conductive pattern 122 may be exposed on a bottom of the first lower electrode hole 132H1. In embodiments, the second lower electrode hole 132H2 may extend in the vertical direction Z so that the upper surface of the second conductive pattern 124 may be exposed on a bottom of the second lower electrode hole 132H2.

A process of forming the first lower electrode hole 132H1 and the second lower electrode hole 132H2 in FIGS. 5A, 5B, 6A, and 6B, is illustrated as a single patterning process, but the disclosure is not limited thereto. In another embodiment, the first lower electrode hole 132H1 and the second lower electrode hole 132H2 may each be formed by a double patterning or quadruple patterning process.

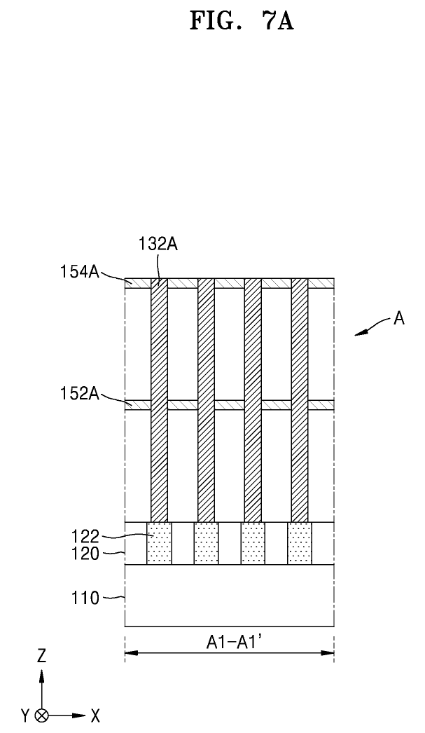

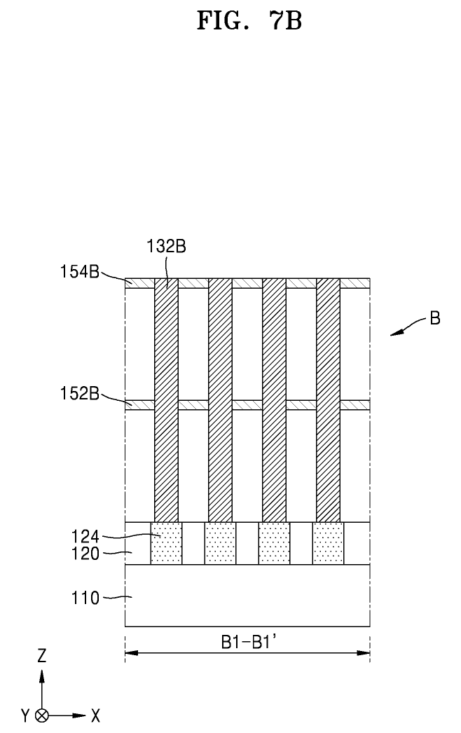

Referring to FIGS. 7A and 7B, the first lower electrode 132A may be formed by filling a conductive material into the first lower electrode hole 132H1, and the second lower electrode 132B may be formed by filling the conductive material into the second lower electrode hole 132H2.

In embodiments, a process of forming the first lower electrode 132A in the first lower electrode hole 132H1 may be performed in the same stage as a process of forming the second lower electrode 132B in the second lower electrode hole 132H2. For example, the first lower electrode 132A may comprise the same material as the second lower electrode 132B.

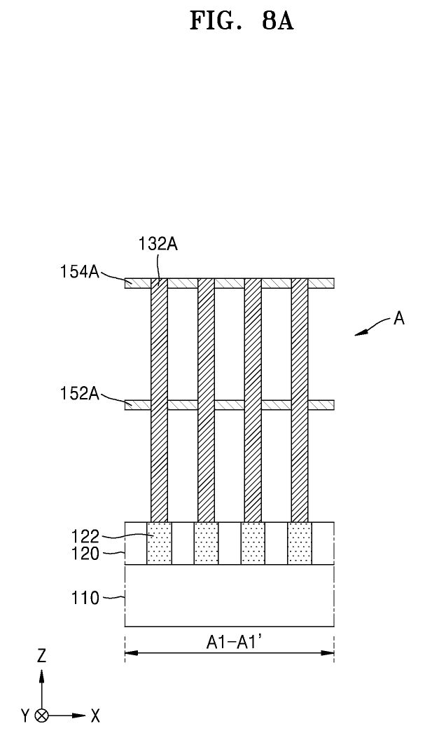

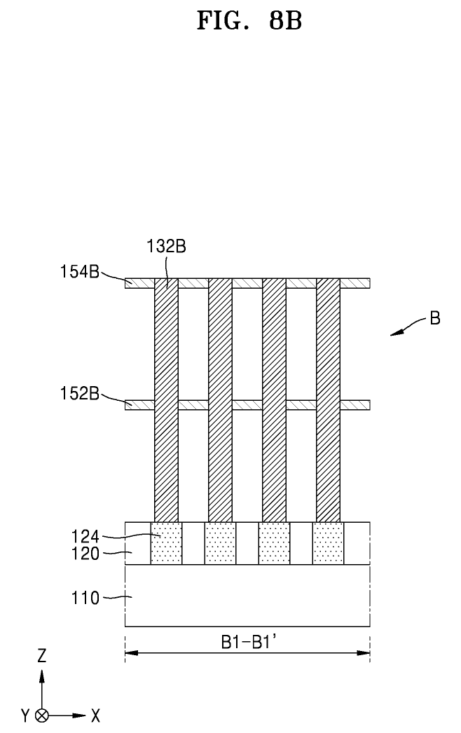

Referring to FIGS. 8A and 8B, the second mold insulating layer 144 may be removed in the first area A and the second area B. A removal process of the second mold insulating layer 144 may be a wet etching process. In a process of removing the second mold insulating layer 144, a portion of the second mold insulating layer 144 on the first area A may be removed, and an upper side of the sidewall of the first lower electrode 132A may be exposed. In addition, in the process of removing the second mold insulating layer 144, a portion of the second mold insulating layer 144 on the second area B may be removed, and an upper side of the sidewall of the second lower electrode 132B may be exposed.

Thereafter, the first mold insulating layer 142 may be removed from the first area A and the second area B. A removal process of the first mold insulating layer 142 may be a wet etching process. In a process of removing the first mold insulating layer 142, a portion of the first mold insulating layer 142 on the first area A may be removed, and a lower side of the sidewall of the first lower electrode 132A may be exposed. In addition, in the process of removing the first mold insulating layer 142, a portion of the first mold insulating layer 142 on the second area B may be removed, and a lower side of the sidewall of the second lower electrode 132B may be exposed.

While the first mold insulating layer 142 and the second mold insulating layer 144 are removed, the first supporter layer 152 and the second supporter layer 154 may remain without being removed and may be arranged to be spaced apart from each other in the vertical direction on the sidewall of the first lower electrode 132A and the sidewall of the second lower electrode 132B. The first supporter layer 152 and the second supporter layer 154 remaining in the first area A may be referred to as the first lower supporter pattern 152A and the first upper supporter pattern 154A. The first supporter layer 152 and the second supporter layer 154 remaining in the second area B may be referred to as the second lower supporter pattern 152B and the second upper supporter pattern 154B, respectively.

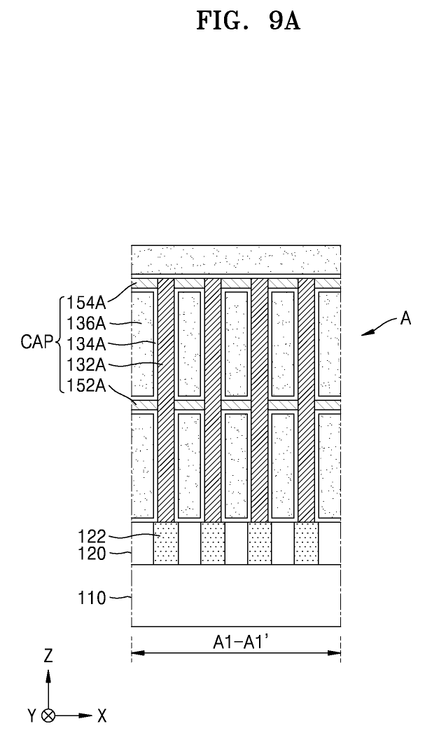

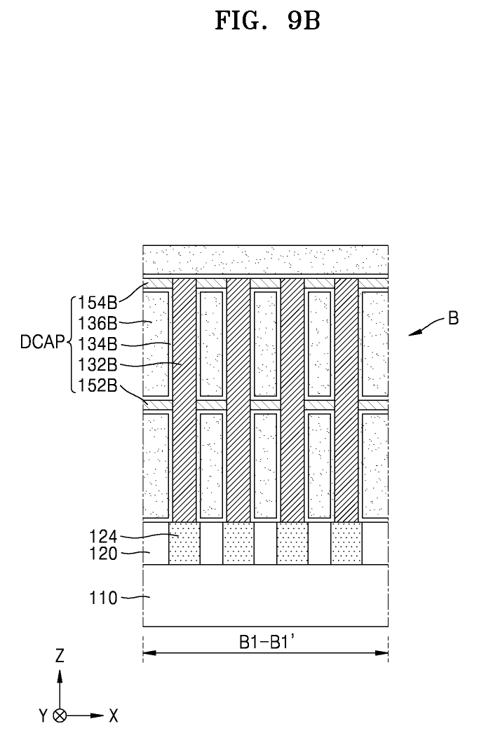

Referring to FIGS. 9A and 9B, the first capacitor dielectric layer 134A may be formed on the sidewall of the first lower electrode 132A, the top and bottom surfaces of the first lower supporter pattern 152A, and the top and bottom surfaces of the first upper supporter pattern 154A. Thereafter, the first upper electrode 136A may be formed on the first capacitor dielectric layer 134A. The first upper electrode 136A may be formed at a certain height on the upper surface of the first upper supporter pattern 154A.

In addition, the second capacitor dielectric layer 134B may be formed on the sidewall of the second lower electrode 132B, the upper surface and the bottom surface of the second lower supporter pattern 152B, and the upper surface and the bottom surface of the second upper supporter pattern 154B. Thereafter, the second upper electrode 136B may be formed on the second capacitor dielectric layer 134B. The second upper electrode 136B may be formed at a certain height on the upper surface of the second upper supporter pattern 154B.

Referring again to FIGS. 3A and 3B, the upper insulating layer 170 may be formed in the first area A and the second area B. The upper insulating layer 170 may be formed to cover the first upper electrode 136A and the second upper electrode 136B. The upper insulating layer 170 may be formed to cover the entire first area A and the second area B, and may have a flat upper surface over the entire first area A and the second area B.

Thereafter, a mask pattern may be formed on the upper insulating layer 170 and the first contact hole 172H and the second contact hole 174H may be formed using the mask pattern as an etching mask. Thereafter, the first upper contact 172 may be formed in the first contact hole 172H and the second upper contact 174 may be formed in the second contact hole 174H. The first upper contact 172 may be electrically connected to the first upper electrode 136A, and the second upper contact 174 may be electrically connected to the second upper electrode 136B.

The semiconductor device 100 may be completed by performing the above-described method.

While aspects of the disclosure have been particularly shown and described with reference to embodiments thereof, it will be understood by those skilled in the art that various changes in form and details may be made without departing from the spirit and scope of the disclosure described in the following claims.

What is claimed is:

1. A semiconductor device comprising:
a substrate comprising a cell array area and a peripheral circuit area;
a cell capacitor in the cell array area and comprising one or more first lower electrodes, a first capacitor dielectric layer, and a first upper electrode; and
a decoupling capacitor in the peripheral circuit area and comprising one or more second lower electrodes, a second capacitor dielectric layer, and a second upper electrode,
wherein, in a plan view, a first arrangement structure of the one or more first lower electrodes is different from a second arrangement structure of the one or more second lower electrodes.

2. The semiconductor device of claim 1, wherein
respective ones of the one or more first lower electrodes are at respective corners of a quadrangle, and
respective ones of the one or more second lower electrodes are at respective vertices of a hexagon and at a center of the hexagon.

3. The semiconductor device of claim 2, wherein
the respective ones of the one or more first lower electrodes are spaced apart by a first distance in a first horizontal direction and by a second distance in a second horizontal direction intersecting the first horizontal direction, and
the first distance is equal to the second distance.

4. The semiconductor device of claim 3, wherein
the respective ones of the one or more second lower electrodes are spaced apart by a third distance in the first horizontal direction and by a fourth distance in the second horizontal direction,
the third distance is equal to the first distance, and
the fourth distance is greater than the first distance.

5. The semiconductor device of claim 4, wherein the hexagon is a regular hexagon.

6. The semiconductor device of claim 1, wherein a diameter of the one or more first lower electrodes is less than a diameter of the one or more second lower electrodes.

7. The semiconductor device of claim 1, wherein
the decoupling capacitor is in a decoupling capacitor area,
the decoupling capacitor area is in the peripheral circuit area, and
an area occupied by the first lower electrode per unit area in the cell array area is less than an area occupied by the second lower electrode per the unit area in the decoupling capacitor area.

8. The semiconductor device of claim 1, wherein
the cell capacitor further comprises one or more first supporter patterns on a portion of a sidewall of the one or more first lower electrodes, and
the decoupling capacitor further comprises one or more second supporter patterns on a portion of a sidewall of the one or more second lower electrodes.

9. The semiconductor device of claim 8, wherein, in the plan view, an arrangement of the one or more first supporter patterns is different from an arrangement of the one or more second supporter patterns.

10. The semiconductor device of claim 1, further comprising:
an upper insulating layer on the first upper electrode and the second upper electrode;
a first upper contact penetrating the upper insulating layer and electrically connected to the first upper electrode; and
a second upper contact penetrating the upper insulating layer and electrically connected to the second upper electrode.

11. A semiconductor device comprising:
a substrate comprising a cell array area and a peripheral circuit area;
a cell capacitor in the cell array area and comprising a plurality of first lower electrodes, a first capacitor dielectric layer, and a first upper electrode; and
a decoupling capacitor in the peripheral circuit area, and comprising a plurality of second lower electrodes, a second capacitor dielectric layer, and a second upper electrode,
wherein the plurality of first lower electrodes comprises a first arrangement structure in which the plurality of first lower electrodes occupy a first area per unit area in a plan view,
wherein the plurality of second lower electrodes comprises a second arrangement structure in which the plurality of second lower electrodes occupy a second area per unit area in the plan view, and
the second area is greater than the first area.

12. The semiconductor device of claim 11, wherein
in the first arrangement structure, respective ones of the plurality of first lower electrodes are at respective corners of a quadrangle, and
in the second arrangement structure, respective ones of the plurality of second lower electrodes are at respective vertices of a hexagon and at a center of the hexagon.

13. The semiconductor device of claim 12, wherein,
in the first arrangement structure, the respective ones of the plurality of first lower electrodes are spaced apart by a first distance in a first horizontal direction and by a second distance in a second horizontal direction intersecting the first horizontal direction, wherein the first distance is equal to the second distance, and
in the second arrangement structure, the respective ones of the plurality of second lower electrodes are spaced apart by a third distance in the first horizontal direction and by a fourth distance in the second horizontal direction, wherein the third distance is different from the fourth distance.

14. The semiconductor device of claim 13, wherein,
in the second arrangement structure, the respective ones of the plurality of second lower electrodes are spaced apart by a fifth distance in a diagonal direction at an angle with the first horizontal direction.

15. The semiconductor device of claim 11, wherein a diameter of each of the plurality of first lower electrodes is less than a diameter of each of the plurality of second lower electrodes.

16. The semiconductor device of claim 11, wherein
in the first arrangement structure, respective ones of the plurality of first lower electrodes are at respective corners of a quadrangle, and
in the second arrangement structure, respective ones of the plurality of second lower electrodes are at respective vertices of a polygon comprising a shape different from the quadrangle.

17. The semiconductor device of claim 11, wherein
the cell capacitor further comprises one or more first supporter patterns between respective ones of the plurality of first lower electrodes,
the decoupling capacitor further comprises one or more second supporter patterns between respective ones of the plurality of second lower electrodes, and
a third density per unit area of the one or more first supporter patterns is greater than a fourth density per unit area of the one or more second supporter patterns.

18. A semiconductor device comprising:
a substrate comprising a cell array area and a peripheral circuit area;
a cell capacitor in the cell array area, the cell capacitor comprising:
a plurality of first lower electrodes extending in a direction perpendicular to an upper surface of the substrate,
a first capacitor dielectric layer on the plurality of first lower electrodes, and
a first upper electrode on the first capacitor dielectric layer; and
a decoupling capacitor on the peripheral circuit area, the decoupling capacitor comprising:
a plurality of second lower electrodes extending in the direction perpendicular to the upper surface of the substrate,
a second capacitor dielectric layer on the plurality of second lower electrodes, and
a second upper electrode on the second capacitor dielectric layer,
wherein respective ones of the plurality of first lower electrodes are at respective corners of a square, and
wherein respective ones of the plurality of second lower electrodes are at respective vertices of a regular hexagon and at a center of the regular hexagon.

19. The semiconductor device of claim 18, wherein
a first horizontal separation distance between the respective ones of the plurality of first lower electrodes is equal to a second horizontal separation distance between the respective ones of the plurality of second lower electrodes.

20. The semiconductor device of claim 18, wherein,
in a plan view, an area occupied by the plurality of first lower electrodes per unit area is less than an area occupied by the plurality of second lower electrodes per the unit area.
